(19) United States
(12) Patent Application Publication
(10) Pub. No.: US 2025/0210428 A1
(43) Pub. Date: Jun. 26, 2025

(54) STIFFENER ASSEMBLY

(71) Applicant: Intel Corporation, Santa Clara, CA (US)

(72) Inventors: Mohan Prashanth Javare Gowda, Ottobrunn (DE); Bernd Waidhas, Pettendorf (DE); Lizabeth Keser, San Diego, CA (US); Cindy Muir, Tempe, AZ (US); Stephan Stoeckl, Schwandorf (DE); Eduardo De Mesa, Munich (DE); Stefan Reif, Munich (DE); Vishnu Prasad, Munich (DE); Georg Seidemann, Landshut (DE)

(21) Appl. No.: 18/389,859

(22) Filed: Dec. 20, 2023

(51) Int. Cl. H01L 23/24; H01L 25/00; H01L 25/065

(52) U.S. Cl. CPC H01L 23/24; H01L 25/50; H01L 25/0655; H01L 2225/065

(57) ABSTRACT

There may be provided a stiffener assembly for a semiconductor package. The stiffener assembly may include a corner member and a frame member. A primary mating element of the corner member and a secondary mating element of the frame member may be configured to interlock with each other to form a connection joint that permits movement of the secondary mating element relative to the primary mating element.

### BACKGROUND

Traditionally, various approaches have been employed to address warpage issues in semiconductor packages.

Some of these approaches involve employing relatively thick integrated heat spreaders on the top side of a substrate within a semiconductor package. Additionally, techniques such as increasing substrate or core thickness, adjusting chip thickness, and selectively choosing materials for different package components to minimize coefficient of thermal expansion (CTE) mismatch have been implemented.

However, these approaches have their drawbacks. Firstly, the use of thick integrated heat spreaders results in an overall increase in the size and weight of a package, accompanied by additional material costs and increased process complexity. Secondly, the incorporation of thicker substrates or cores, while intended to control warpages, also leads to an overall increase in package height. Moreover, the effectiveness of warpage control through material selection is limited by the limited availability of materials possessing the required properties.

In light of these limitations, there is a need for an improved approach to address warpage issues in semiconductor packages.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. In the following description, various aspects are described with reference to the following drawings, in which:

FIG. 1A is a schematic diagram depicting a side view of a semiconductor assembly, in an unwarped state, according to various aspects;

FIG. 1B is a schematic diagram depicting a plan view of the semiconductor assembly of FIG. 1A and a stiffener assembly, according to various aspects;

FIG. 1C is a schematic side view of the semiconductor assembly warped in a first manner, according to various aspects;

FIG. 1D is a schematic plan view of the semiconductor assembly of FIG. 1C, according to various aspects;

FIG. 1E is a schematic side view of the semiconductor assembly warped in a second manner, according to various aspects;

FIG. 1F is a schematic plan view of the semiconductor assembly of FIG. 1E, according to various aspects;

FIG. 2A is a perspective view of a stiffener assembly which includes a corner member and a plurality of frame members which are interlocking with the corner member, according to various aspects;

FIG. 2B is an isolated perspective view of the corner member of the stiffener assembly of FIG. 2A, according to various aspects;

FIG. 2C is an isolated perspective view of a frame member of the stiffener assembly of FIG. 2A, according to various aspects;

FIG. 2D is a plan view of the stiffener assembly of FIG. 2A, according to various aspects;

FIG. 2E is a plan view of a stiffener assembly within a semiconductor assembly, according to various aspects;

FIG. 2F is an isolated perspective view of an interlocked corner member and four frame members of the stiffener assembly of FIG. 2E, during a first warpage condition of the semiconductor assembly of FIG. 2E, according to various aspects;

FIG. 2G is an isolated perspective view of an interlocked corner member and four frame members of the stiffener assembly of FIG. 2E, during a second warpage condition of the semiconductor assembly of FIG. 2E, according to various aspects;

FIG. 3A is a perspective view of a stiffener assembly which includes a corner member interlocking with a plurality of frame members at each primary mating element of the corner member, according to various aspects;

FIG. 3B is a side view of a semiconductor assembly having the stiffener assembly of FIG. 3B attached to an interposer, according to various aspects;

FIG. 3C is an isolated plan view of the corner member and upper frame members of the stiffener assembly at an upper region of the corner member, when the semiconductor assembly of FIG. 3B is warped in a first manner, according to various aspects;

FIG. 3D is an isolated plan view of the corner member and bottom frame members at a bottom region of the corner member, when the semiconductor assembly of FIG. 3B is warped in the first manner, according to various aspects;

FIG. 3E is an isolated plan view of the corner member and upper frame members of the stiffener assembly at an upper region of the corner member, when the semiconductor assembly of FIG. 3B is warped in a second manner, according to various aspects;

FIG. 3F is an isolated plan view of the corner member and bottom frame members at a bottom region of the corner member, when the semiconductor assembly of FIG. 3B is warped in the second manner, according to various aspects; and

FIG. 4 is a flow chart depicting a method, according to various aspects.

### DETAILED DESCRIPTION

Aspects described below in the context of the apparatus are analogously valid for the respective methods, and vice versa. Furthermore, it will be understood that the aspects described below may be combined, for example, a part of one aspect may be combined with a part of another aspect.

It should be understood that the terms “on”, “over”, “top”, “bottom”, “down”, “side”, “back”, “left”, “right”, “front”, “lateral”, “side”, “up”, “down” etc., when used in the following description are used for convenience and to aid understanding of relative positions or directions, and not intended to limit the orientation of any device, or structure or any part of any device or structure. In addition, the singular terms “a”, “an”, and “the” include plural references unless context clearly indicates otherwise. Similarly, the word “or” is intended to include “and” unless the context clearly indicates otherwise.

Various aspects generally relate to a stiffener assembly (e.g. a stiffener), which may be included in or may be an apparatus, capable of regulating and managing warpage in a semiconductor assembly (e.g. a semiconductor package). The warping in the semiconductor assembly may arise due to different components of the semiconductor assembly being constructed from materials having varying coefficients of thermal expansion (CTEs).

The semiconductor assembly may include several discrete components. For example, the semiconductor assembly may include layers(s), such as substrate(s), core(s), interposer(s), panel(s), etc., (which may be referred to as “semiconductor substrate” for simplicity), and/or one or more other semiconductor component(s), such as die(s), chip(s) or chip module(s), chiplet(s), processor(s), transistor(s), etc., situated on the semiconductor substrate. The materials of these components within the semiconductor assembly may have different CTEs relative to each other, causing them to expand or contract at different rates, especially in response to temperature fluctuations.

The stiffener assembly, according to the various aspects, may be coupled (e.g. affixed) to the semiconductor assembly, specifically to at least two different components of the semiconductor assembly having varying CTE values, to effectively control and manage any warpage that may occur in the semiconductor assembly.

Particularly, the stiffener assembly, according to the various aspects, may include at least two members, such as a corner member (also known as a “Jig-Via-Block coupler”) and a frame member (also known as a “stiffener brace” or “stiffener beam brace”), described in detail later, which may be coupled (e.g. directly or indirectly coupled) to at least two different components of the semiconductor assembly having varying CTE values. These members (e.g. corner member and frame member) of the stiffener assembly may be configured to mate and/or interact with each other in a way which allows or permits movement of these members relative to each other in a limited manner. In other words, through their mating and/or interaction, these members of the stiffener assembly may be movable over a limited range or distance and/or in predetermined direction(s). Consequently, the components of the semiconductor assembly coupled with these members of the stiffener assembly may also only experience limited movement (e.g. limited warping) since they are constrained by these members of the stiffener assembly.

According to various aspects, a size, shape, profile, orientation, and/or position of the members of the stiffener assembly may be customizable or adjustable depending on their application, specific package (e.g. chip-package) configuration, etc.

Accordingly, the stiffener assembly, according to the various aspects, may be integrated into any semiconductor package or packaging (e.g. a wafer-level packaging or a panel-level packaging with larger aspect ratios), while offering advantages such as enhanced package reliability, ease of assembly handling, improved yield, and prolonged performance lifespan.

In addition to the mentioned benefits, the members (e.g. corner member and frame member) of the stiffener assembly, when attached to the semiconductor assembly (e.g. a semiconductor package), may be configured to function or serve as channels (or routes) for power and/or thermal distribution within the semiconductor assembly (e.g. the semiconductor package).

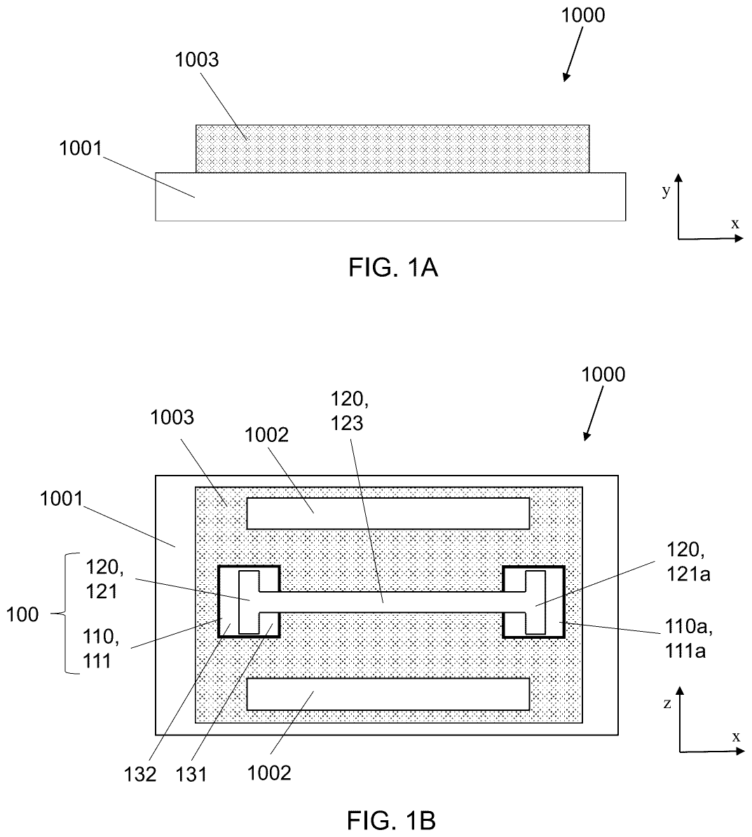

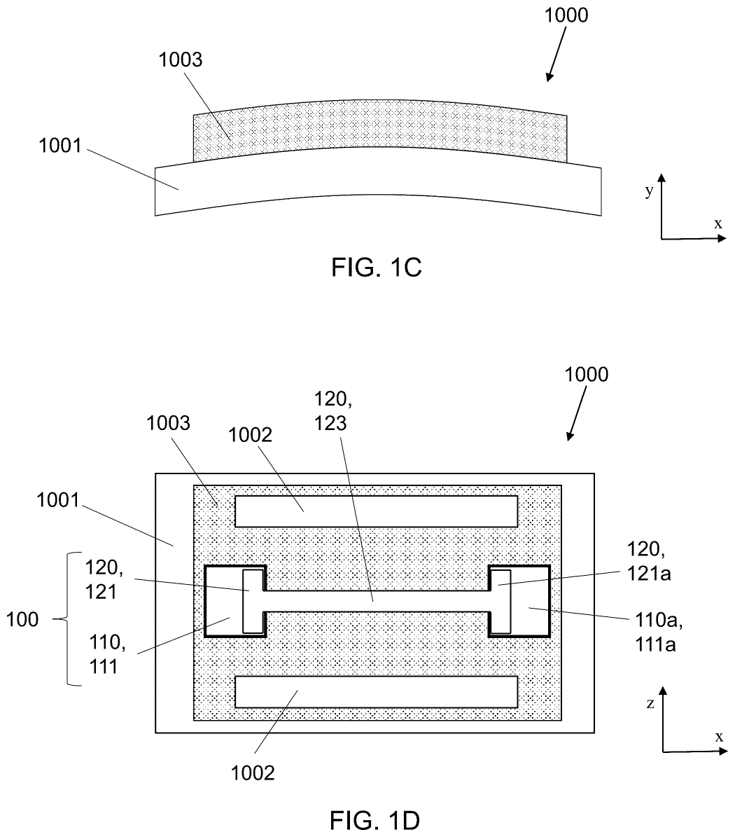

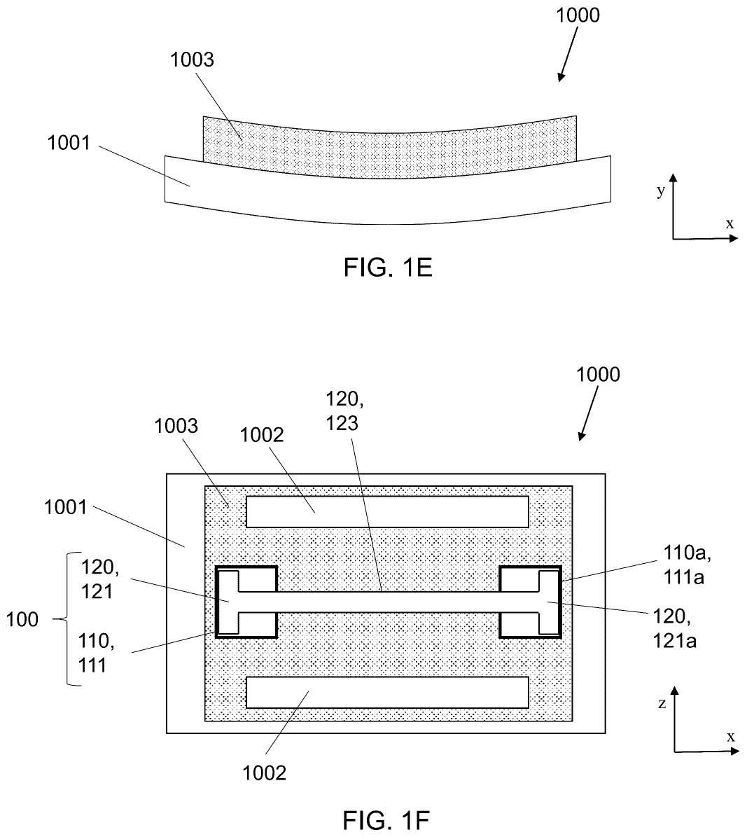

FIG. 1A is a schematic diagram depicting a side view of a semiconductor assembly, in an unwarped state, according to various aspects.

FIG. 1B is a schematic diagram depicting a plan view of the semiconductor assembly of FIG. 1A and a stiffener assembly, according to various aspects.

Referring to FIG. 1B, according to various aspects, there may be provided a stiffener assembly 100 for a semiconductor assembly 1000. According to various aspects, the stiffener assembly 100 may be included in or may be part of an apparatus configured to be integrated into or within (e.g. attached to at least a portion of) the stiffener assembly 100 to enhance the mechanical integrity or rigidity of the semiconductor assembly 1000.

According to various aspects, the stiffener assembly 100 may include structural members (or components, modules, units, or elements) for enhancing the mechanical stability of the semiconductor assembly 1000. Specifically, with reference to FIG. 1B, according to various aspects, the stiffener assembly 100 may include, at least, a corner member 110 (e.g. a first member, which may serve as an anchor member) and a frame member 120 (e.g. a second member, which may serve as a warpage-control member). The corner member 110 and the frame member 120 may be discrete (e.g. individual) components of the stiffener assembly 100 which may be interlocked with each other to form a fully assembled stiffener assembly 100.

According to various aspects, the corner member 110 (e.g. first member) of the stiffener assembly 100 may be configured to be coupled (e.g. directly or indirectly coupled, connected, attached, and/or secured) to a first component 1001 (e.g. a semiconductor substrate) of the semiconductor assembly 1000. According to various aspects, with the corner member 110 coupled to the first component 1001 of the semiconductor assembly 1000, the corner member 110 (e.g. the entire corner member 110) may be immovable relative to the first component 1001 of the semiconductor assembly 1000. Additionally, according to various aspects, the corner member 110 may (e.g. optionally) be configured (e.g. shaped, sized, and/or composed of a hard and/or rigid material) in a manner which prevents the corner member 110 from warping or bending. As some examples, the corner member 110 may be attached or secured to the first component 1001 (e.g. semiconductor substrate) of the semiconductor assembly 1000 by employing an adhesive, fastener(s), soldering, etc., or by employing any other attachment mechanism.

According to various aspects, the corner member 110 of the stiffener assembly 100 may be disposed proximal or relative to the first component 1001 of the semiconductor assembly 1000 in any suitable manner. For example, the entire corner member 110 may be on (e.g. sitting on) or over an outer (e.g. an upper or topmost) surface of the first component 1001 (e.g. semiconductor substrate) of the semiconductor assembly 1000. As another example, a portion of the corner member 110 may be within (e.g. embedded within or inserted into) the first component 1001 (e.g. semiconductor substrate) of the semiconductor assembly 1000. For instance, the first component 1001 (e.g. semiconductor substrate) of the semiconductor assembly 1000 may include a through-hole or a via (e.g. via hole) for receiving at least a portion of the corner member 110 therewithin. In this manner, a remaining (e.g. an upper) portion of the corner member 110 may be extending or protruding outwards of the first component 1001 (e.g. semiconductor substrate) of the semiconductor assembly 1000 (e.g. from its upper surface). Consequently, the aforementioned protruding portion of the corner member 110 may be free to mate (e.g. interlock) with the frame member 120 to form a fully assembled stiffener assembly 100.

According to various aspects, the frame member 120 (e.g. second member) of the stiffener assembly 100 may be configured to be coupled (e.g. directly or indirectly coupled, connected, attached, and/or secured) to one or more second components 1002 (e.g. chips, chiplets, etc.) of the semiconductor assembly 1000. Said one or more second components 1002 (e.g. chips, chiplets, etc.) may be disposed on the aforementioned first component 1001 (e.g. semiconductor substrate) of the semiconductor assembly 1000 (e.g. disposed on an upper surface of the semiconductor substrate). For ease of description, various aspects may be illustrated or described with reference to a plurality of second components 1002 (e.g. chips, chiplets, etc.). For instance, FIG. 1B may illustrate two ‘second components’ 1002. Nevertheless, various aspects illustrated or described as such are not limited thereto. Thus, for example, various aspects made with reference to a plurality of second components 1002 may be applicable with respect to any other number of second component(s) (e.g. one ‘second component’, three ‘second components’ 1002, or more than three ‘second components’ 1002).

According to various aspects, the frame member 120 of the stiffener assembly 100 may also be coupled (e.g. directly or indirectly coupled) to the first component 1001 (e.g. the semiconductor substrate) of the stiffener assembly 100.

According to various aspects, the stiffener assembly 100 may include (e.g. further include) an intervening element 1003, such as a mold material or mold compound, that connects or couples the frame member 120 of the stiffener assembly 100 and the second components 1002 (e.g. chips, chiplets, etc.) of the semiconductor assembly 1000. For example, the intervening element 1003 (e.g. mold material) may encapsulate or encase at least a portion of the frame member 120 and at least a portion of the second components 1002 (e.g. chips, chiplets, etc.) of the semiconductor assembly 1000. The intervening element 1003 may form a continuous trail between the frame member 120 and the second components 1002 of the semiconductor assembly 1000, thereby connecting or coupling the frame member 120 and the second components 1002. According to various aspects, as an example, depicted in FIG. 1A, the intervening element 1003 may be disposed on an upper surface of the first component 1001 (e.g. upper surface of a semiconductor substrate). According to various aspects, the intervening element 1003 (e.g. mold material) may be solidified (e.g. by undergoing a curing process, as required).

According to various aspects, with the frame member 120 of the stiffener assembly 100 connected or coupled to the second components 1002 (e.g. chips, chiplets, etc.) of the semiconductor assembly 1000, any movement (e.g. warpage, bending, etc.) of the second components 1002 of the semiconductor assembly 1000 may result in corresponding movement of the frame member 120. Correspondingly, an extent to which the second components 1002 of the semiconductor assembly 1000 may be moved (e.g. warped) may be limited by an extent to which the frame member 120 is permitted to move within the stiffener assembly 100 (i.e. within a fully assembled stiffener assembly 100).

According to various aspects, the frame member 120 may be disposed proximal or relative to the first component 1001 (e.g. the semiconductor substrate) of the semiconductor assembly 1000. For example, the entire frame member 120 of the stiffener assembly 100 may be on (e.g. sitting on) or over an outer (e.g. an upper or topmost) surface of the first component 1001 (e.g. semiconductor substrate) of the semiconductor assembly 1000. In this manner, the frame member 120 of the stiffener assembly 100 may be adjacent, alongside, between, and/or among the second components 1002 (e.g. chips, chiplets, etc.) of the semiconductor assembly 1000. As another example, the frame member 120 may be within (e.g. entirely or partially embedded within) the first component 1001 (e.g. the semiconductor substrate) of the semiconductor assembly 1000. For instance, the frame member 120 may be at or along an upper or topmost portion or region of the first component 1001 (e.g. the semiconductor substrate).

According to various aspects, the corner member 110 and the frame member 120, of the stiffener assembly 100, may be configured to inter-mate (e.g. interlock) with each other in a manner such that the frame member 120 of the stiffener assembly 100 may be movable or displaceable relative to the corner member 110 (i.e. while they are interlocked with each other), but in a limited manner. In other words, said relative movement or displacement of the frame member 120 may be confined to a predetermined or defined range and/or in one or more predetermined or defined direction(s).

To illustrate, the corner member 110 of the stiffener assembly 100 may include a primary mating element 111 (e.g. a coupling or connecting element or portion), while the frame member 120 of the stiffener assembly 100 may include a secondary mating element 121 (e.g. a coupling or connecting element or portion). The primary mating element 111 of the corner member 110 and the secondary mating element 121 of the frame member 120 may be configured to interlock with each other to form a connection joint that permits movement (e.g. limited movement) of the secondary mating element 121 relative to (e.g. within) the primary mating element 111, in one or more directions (e.g. in the x-axis, and/or z-axis, etc.). In other words, according to various aspects, the stiffener assembly 100 may have a tolerance between the primary mating element 111 of the corner member 110 and the secondary mating element 121 of the frame member 120 which allows some degree of movement of the secondary mating element 121 relative to the primary mating element 111 while they are interlocked.

As an example, according to various aspects, the primary mating element 111 of the corner member 110 may include or may be (e.g. may be configured as) an opening (e.g. receptacle, socket, channel, slot, etc.) configured (e.g. shaped and/or sized) to receive, hold, and/or retain the secondary mating element 121 of the frame member 120 therewithin. On the other hand, the secondary mating element 121 of the frame member 120 may include or may be (e.g. may be configured as) an insert (e.g. an insert member or insert portion, a plug, a tab, a head, etc.), or more specifically may be an end portion of the frame member 120, that may be configured (e.g. shaped and/or sized) to be insertable into (in other words, removably insertable into) the opening (i.e. the primary mating element 111) to form the connection joint between the primary mating element 111 and the secondary mating element 121. According to various aspects, with (e.g. when) the insert (i.e. the secondary mating element 121) is inserted into the opening (i.e. the primary mating element 111) to form the connection joint, an inner surface of the corner member 110 which defines the opening (i.e. the primary mating element 111) may be at least partially surrounding, or may be substantially surrounding, a side surface (e.g. a continuous side surface, or all side surfaces) of the insert (i.e. the secondary mating element 121). For instance, with reference to FIG. 1B, when the insert (i.e. the secondary mating element 121) is a rectangular shaped insert having four side surfaces, the opening (i.e. the primary mating element 111) may be surrounding the (rectangular shaped) insert along its four side surfaces (e.g. substantially entirely, or along at least a portion of each side surface thereof).

Additionally, according to various aspects, a shape (e.g. a lateral cross-sectional profile) of the opening (i.e. the primary mating element 111) may correspond (e.g. may be similar or identical) to (or may match) a shape (e.g. a lateral cross-sectional profile) of the insert (i.e. the secondary mating element 121), while a size of the opening (i.e. the primary mating element 111) may be larger than a size of the insert (i.e. the secondary mating element 121). Accordingly, the opening (i.e. the primary mating element 111) may permit movement (e.g. limited movement) or displacement of the insert (i.e. the secondary mating element 121) within the opening.

It is envisaged that, in other implementations, the insert (i.e. the secondary mating element 121) may have any other shape (e.g. a triangular shape, square shape, hexagonal shape, circular shape, ellipse shape, etc.) and the opening (i.e. the primary mating element 111) may have a shape that may be similar or identical to the shape of the insert (i.e. the secondary mating element 121).

It is also envisaged that, in other implementations, the secondary mating element 121 of the frame member 120 may include or may be (e.g. may be configured as) an opening, while the primary mating element 111 of the corner member 110 may include or may be (e.g. may be configured as) an insert (e.g. at an end portion of the corner member 110). Accordingly, in other implementations, the primary mating element 111 may be inserted into the secondary mating element 121 to form the connection joint which permits movement (e.g. the limited movement) of the secondary mating element 121 relative to the primary mating element 111.

With reference to FIG. 1B, according to various aspects, the frame member 120 may be elongate in form (in other words, have an elongate shape). Specifically, the frame member 120 may include an elongate body 123 (e.g. resembling a beam). According to various aspects, the elongate body 123 may have a uniform cross-sectional profile. According to various aspects, the elongate body 123 of the frame member 120 may be configured to be capable of bending or flexing (e.g. when under the influence of an external force), and/or may be capable of expansion or contraction, etc., for instance, in tandem with the second components 1002 (e.g. chips, chiplets, etc.) of the semiconductor assembly 1000 (i.e. which may be coupled to the frame member 120). According to various aspects, the secondary mating element 121 may be integral (e.g. integrally formed) with the elongate body 123. Accordingly, when the elongate body 123 of the frame member 120 bends or flexes, it may cause the secondary mating element 121 of the frame member 120 to move relative to the primary mating element 111 of the corner member 110, within the stiffener assembly 100.

According to various aspects, as depicted in FIG. 1B, the secondary mating element 121 may be at a first end (e.g. a first longitudinal end) of the elongate body 123 of the frame member 120.

Additionally, according to various aspects, the frame member 120 may include (e.g. optionally or further include) a further (in other words, an additional or another) secondary mating element 121a (e.g. insert/end portion) at a second end (e.g. a second longitudinal end) of the elongate body 123 of the frame member 120, opposite the first end of the elongate body 123. According to various aspects, the further secondary mating element 121a may be configured to interlock with a second corner member 110a of the stiffener assembly 100, described below.

According to various aspects, the stiffener assembly 100 may include (e.g. optionally or further include) the second corner member 110a (e.g. discrete from the corner member 110). The second corner member 110a may be similar or identical to the corner member 110. Accordingly, as in the corner member 110, the second corner member 110a may include a (e.g. its own respective) primary mating element 111a. As depicted in FIG. 1B, the primary mating element 111a of the second corner member 110a and the further secondary mating element 121a of the frame member 120 may be configured to interlock with each other to form a connection joint (e.g. another or a further connection joint). This connection joint may be configured to permit movement of the further secondary mating element 121a of the frame member 120 relative to the primary mating element 111a of the second corner member 110a.

It is envisaged that, in other implementations, the second end of the frame member 120 may be a free end (e.g. without the second corner member 110a). It is also envisaged that, in other implementations, the second end of the frame member 120 may be coupled (e.g. secured or anchored) to another component (not shown in FIG. 1B), such as another stiffener, a brace structure, or a supporting element (e.g. connected to the semiconductor assembly 1000), which may serve to anchor the second end of the frame member 120 to a point within the semiconductor assembly 1000.

According to various aspects, the corner member 110 may be elongate and/or extending (e.g. longitudinally extending) in a first direction (e.g. relative to the first component 1001, such as a semiconductor substrate). The first direction may be in and/or may be parallel with the y-axis shown in FIG. 1A. That is, the corner member 110 may be extending vertically or substantially vertically.

The frame member 120, on the other hand, may be elongate and/or extending in a second direction that is non-parallel to the first direction. As an example, the second direction may be perpendicular or substantially perpendicular to the first direction. Accordingly, when the first direction is a vertical direction, the second direction may be a horizontal direction. Hence, the frame member 120 may be extending horizontally or substantially horizontally (e.g. such as being parallel with an upper surface of the semiconductor substrate, i.e. the first component 1001). As an example, the frame member 120 may be extending in a direction which may be in and/or may be parallel with the x-axis shown in FIG. 1B. It is envisaged that, in other implementations, the frame member 120 may be extending in any other horizontal direction, or in any other direction that is non-parallel to the first direction.

According to various aspects, the primary mating element 111 of the corner member 110 may be configured to permit movement (e.g. limited movement, in other words, movement within a predetermined or specific range) of the secondary mating element 121 of the frame member 120 in at least the second direction. To this end, with reference to FIG. 1B, a width (e.g. a first width) of the primary mating element 111 (e.g. measured in the x-axis) may be larger or wider than a width (e.g. a first width) of the secondary mating element 121 (e.g. also measured in the x-axis).

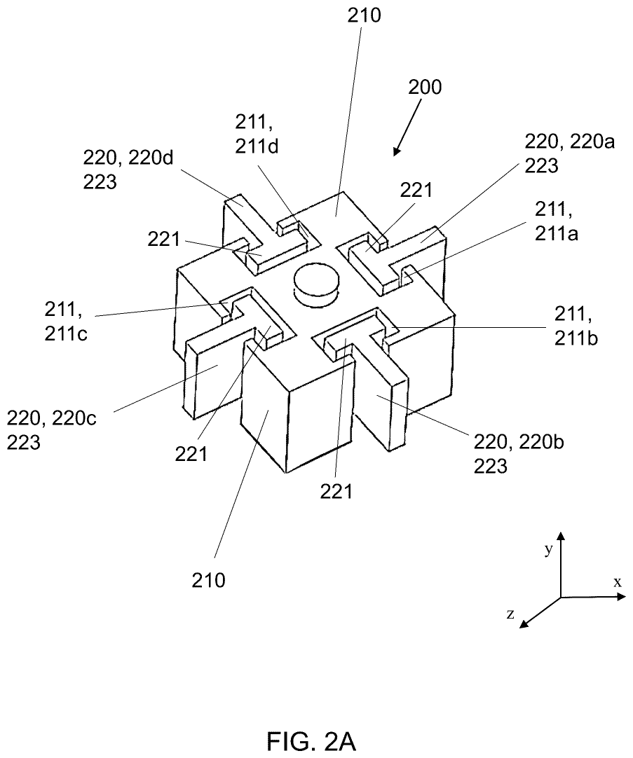

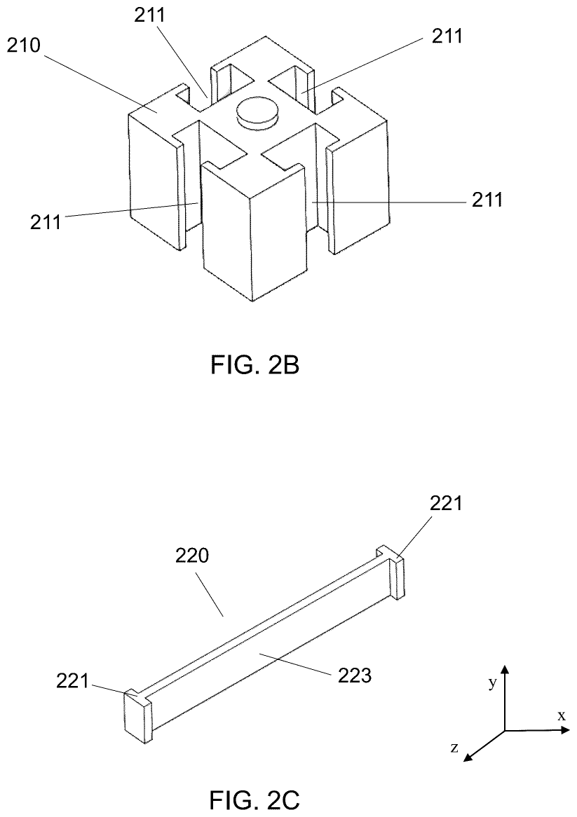

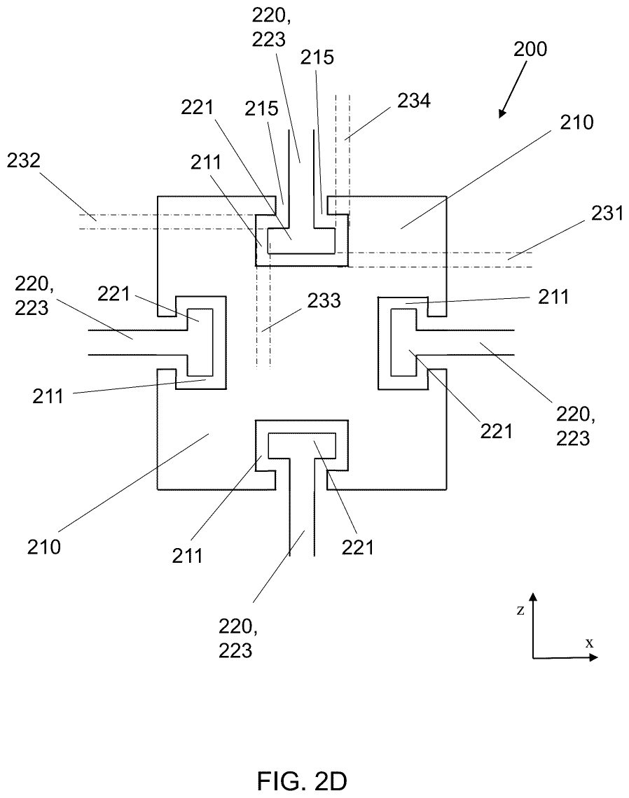

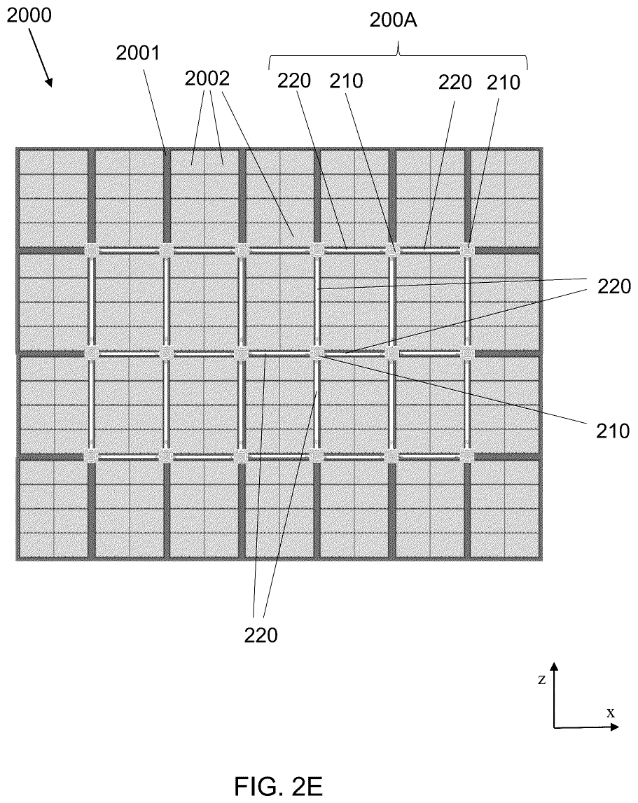

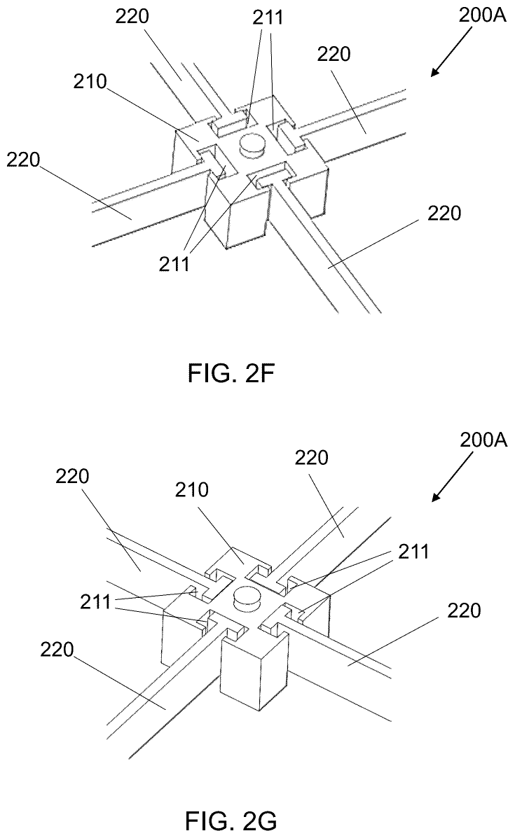

Additionally, or alternatively, according to various other aspects (described in detail later, with reference to FIG. 2D), the primary mating element 111 of the corner member 110 may be configured to permit movement (e.g. limited movement) of the secondary mating element 121 of the frame member 120 in at least a third direction that is non-parallel (e.g. perpendicular or substantially perpendicular) to both the first direction and to the second direction. For example, with the first direction in the y-axis and with the second direction in the x-axis, the third direction may be in the z-axis.

According to various aspects, the stiffener assembly 100 may be configured or assembled in a manner such that, under normal conditions (e.g. which do not result in nor induce any warpage in the semiconductor assembly 1000), the secondary mating element 121 may be spaced apart from one (e.g. only one) or from both inner surfaces of the primary mating element 111 which define the secondary mating element 121 and by which the aforementioned width of the primary mating element 111 is measured. For ease of description, various aspects may be described with respect to the secondary mating element 121 being spaced apart from both (or all) inner surfaces of the primary mating element 111 (i.e. which define the secondary mating element 121 and by which the aforementioned width of the primary mating element 111 is measured), under normal conditions, as depicted in FIG. 1B. Nevertheless, various aspects described as such are not limited thereto. Thus, for example, in other implementations, the secondary mating element 121 may be in contact with at least one inner surface of the primary mating element 111, while being spaced apart from at least one other inner surface of the primary mating element 111 under normal conditions.

FIG. 1C is a schematic side view of the semiconductor assembly warped in a first manner, according to various aspects.

FIG. 1D is a schematic plan view of the semiconductor assembly of FIG. 1C, according to various aspects.

As an example, under a first warpage condition which may cause the semiconductor assembly 1000 to warp in the first manner depicted in FIG. 1C (e.g. resembling a “frown”), the secondary mating element 121 of the frame member 120 may abut against a first inner surface of the corner member 110 which defines the primary mating element 111 (as depicted in FIG. 1D). With the secondary mating element 121 of the frame member 120 abutting the primary mating element 111 of the corner member 110 in this manner (i.e. during the first warpage condition), the stiffener assembly 100 may prevent or restrict the semiconductor assembly 1000 (e.g. at least the first component 1001 and/or second components 1002 of the semiconductor assembly 1000, which may be directly or indirectly coupled or connected to the frame member 120) from potentially warping any further or excessively, thereby controlling an extent of warpage the semiconductor assembly 1000 may experience.

As depicted in FIG. 1D, the primary mating element 111 (e.g. an opening) of the corner member 110 may be configured (e.g. shaped and/or sized) to restrict the secondary mating element 121 (e.g. end portion) of the frame member 120 and, by extension, the first component 1001 and/or second components 1002 of the semiconductor assembly 1000 (i.e. coupled or connected to the frame member 120) from potentially warping any further or excessively, when the semiconductor assembly 1000 is subject to the first warpage condition. Accordingly, an extent of warpage that the semiconductor assembly 1000 may experience under the first warpage condition may correspond to a first spacing (or gap) 131 (see FIG. 1B) existing between the secondary mating element 121 and the primary mating element 111 under normal conditions.

Correspondingly, as depicted in FIG. 1D, the second corner member 110a (i.e. opposite the corner member 110) may be configured (e.g. sized) to restrict the further secondary mating element 121a of the frame member 120 and, by extension, the first component 1001 and/or second components 1002 of the semiconductor assembly 1000 (i.e. coupled or connected to the frame member 120) from potentially warping any further or excessively, when the semiconductor assembly 1000 is subject to the first warpage condition.

FIG. 1E is a schematic side view of the semiconductor assembly warped in a second manner, according to various aspects.

FIG. 1F is a schematic plan view of the semiconductor assembly of FIG. 1E, according to various aspects.

As a further example, under a second warpage condition which may cause the semiconductor assembly 1000 to warp in the second manner depicted in FIG. 1E (e.g. resembling a “smile”), the secondary mating element 121 of the frame member 120 may abut against a second inner surface of the corner member 110 defining the primary mating element 111, opposite the first inner surface of the corner member 110 (as depicted in FIG. 1F). With the secondary mating element 121 of the frame member 120 abutting the primary mating element 111 of the corner member 110 in this manner (i.e. during the second warpage condition), the stiffener assembly 100 may prevent or restrict the semiconductor assembly 1000 (e.g. at least the first component 1001 and/or second components 1002 of the semiconductor assembly 1000, which may be directly or indirectly coupled or connected to the frame member 120) from potentially warping any further or excessively, thereby controlling an extent of warpage within the semiconductor assembly 1000.

As depicted in FIG. 1F, the primary mating element 111 (e.g. an opening) of the corner member 110 may be configured (e.g. shaped and/or sized) to restrict the secondary mating element 121 (e.g. end portion) of the frame member 120 and, by extension, the first component 1001 and/or second components 1002 of the semiconductor assembly 1000 (i.e. coupled or connected to the frame member 120) from potentially warping any further or excessively, when the semiconductor assembly 1000 is subject to the second warpage condition. Accordingly, an extent of warpage that the semiconductor assembly 1000 may experience under the second warpage condition may correspond to a second spacing (or gap) 132 (see FIG. 1B) existing between the secondary mating element 121 and the primary mating element 111 under normal conditions.

Correspondingly, as depicted in FIG. 1F, the second corner member 110a (i.e. opposite the corner member 110) may be configured (e.g. shaped and/or sized) to restrict the further secondary mating element 121a (e.g. other end portion) of the frame member 120 and, by extension, the first component 1001 and/or second components 1002 of the semiconductor assembly 1000 (i.e. coupled or connected to the frame member 120) from potentially warping any further or excessively, when the semiconductor assembly 1000 is subject to the second warpage condition.

Referring back to FIG. 1B, according to various aspects, the stiffener assembly 100, the first component 1001, and the second components 1002 (e.g. on the first component 1001) may together form, or may be part of, an assembly. According to various aspects, this assembly may include or may be the semiconductor assembly 1000.

According to various aspects, within the semiconductor assembly 1000, the corner member 110 of the stiffener assembly 100 may be coupled to the first component 1001 (e.g. the semiconductor substrate).

Further, according to various aspects, within the semiconductor assembly 1000, the frame member 120 of the stiffener assembly 100 may be coupled to the second components 1002 (e.g. semiconductor components, such as chips).

Further, within the semiconductor assembly 1000, the corner member 110 of the stiffener assembly 100 may be disposed on an outer (e.g. an upper or topmost) surface of the first component 1001 (e.g. the semiconductor substrate). Alternatively, the corner member 110 may be at least partially within (e.g. embedded within or inserted into) the first component 1001 (e.g. the semiconductor substrate). According to various aspects, the corner member 110 may be extending in or along a thickness direction (or heightwise) of the first component 1001 (e.g. in the y-axis, between a base surface and an upper surface of the semiconductor substrate).

Further, within the semiconductor assembly 1000, the frame member 120 of the stiffener assembly 100 may be disposed on an outer (e.g. an upper or topmost) surface of the first component 1001 (e.g. the semiconductor substrate). Alternatively, the frame member 120 may be at least partially within (e.g. embedded within or inserted into) the first component 1001 (e.g. at or along an upper or topmost portion or region of the semiconductor substrate). According to various aspects, the frame member 120 may be extending horizontally (e.g. in the x-axis, the z-axis, or in any other horizontal direction that may be parallel with an upper surface of the semiconductor substrate, i.e. the first component 1001).

According to various aspects, the semiconductor assembly 1000 may include (e.g. optionally or further include) the intervening element 1003 (e.g. mold material) connecting or coupling the frame member 120 and the second components 1002.

According to various aspects, the corner member 110 and/or the frame member 120 may include or may be composed of an electrically conductive material.

According to various aspects, the corner member 110 and/or the frame member 120 may include or may be composed of a thermally conductive material.

FIG. 2A is a perspective view of a stiffener assembly which includes a corner member and a plurality of frame members which are interlocking with the corner member, according to various aspects.

According to various aspects, there may be provided an apparatus which may include or may be the stiffener assembly 200. According to various aspects, the stiffener assembly 200 may contain any one or more or all the features and/or limitations of the stiffener assembly 100 of FIG. 1A to FIG. 1F. In the following, the stiffener assembly 200 is described with like reference characters generally referring to the same or corresponding parts/features of the stiffener assembly 100 of FIG. 1A to FIG. 1F. The description of the parts/features made with respect to the stiffener assembly 200 may also be applicable with respect to the stiffener assembly 100, and vice versa.

FIG. 2B is an isolated perspective view of the corner member of the stiffener assembly of FIG. 2A, according to various aspects.

Referring to FIG. 2B, according to various aspects, the corner member 210 may include a plurality of primary mating elements 211 (e.g. plurality of openings). For ease of description, various aspects may be described with reference to the corner member 210 having four primary mating elements 211. Nevertheless, it is envisaged that, in other implementations, the corner member 210 may have any other number of primary mating elements 211 (e.g. two, three, or more than three primary mating elements 211).

According to various aspects, as shown in FIG. 2B, the primary mating elements 211 of the corner member 210 may be similarly or identically shaped and/or sized with respect to one another. It is envisaged that, in other implementations, the primary mating elements 211 may have different configurations (e.g. shapes and/or sizes) from one another.

According to various aspects, as shown, each primary mating element 211 of the corner member 210 may be an elongate opening (e.g. an elongate socket or elongate receptacle) that extends from an upper surface (e.g. a first surface) of the corner member 210 towards (or until or to) a base surface (e.g. a second surface) of the corner member 210. In other words, such an elongate opening may extend between the base surface and the opposite upper surface of the corner member 210. Specifically, the primary mating element 211 may be extending vertically or substantially vertically (e.g. in the y-axis). As shown, the primary mating element 211 (e.g. elongate opening) may be configured as, or may resemble, a “channel” or “slot” having a uniform cross-sectional profile. Further, the primary mating element 211 may have an entrance (e.g. a first entrance) at the upper surface of the corner member 210. According to various other aspects, when the primary mating element 211 is configured to extend from the upper surface until the base surface, the primary mating element 211 may have another entrance (e.g. a second entrance) at the base surface of the corner member 210.

According to various aspects, the entire corner member 210 may be a single and/or monolithic structure or entity. That is, the entire corner member 210 may be an integral structure or may be integrally formed (e.g. free from any disparate or separable parts or portions. Accordingly, the primary mating elements 211 may be integral elements or portions of the corner member 210.

Referring to FIG. 2A and FIG. 2B, according to various aspects, the corner member 210 may be a polygonal shaped (e.g. a squarish shaped) corner member 210, having a plurality of sides (e.g. four sides) or side faces. While FIG. 2A and FIG. 2B may illustrate the corner member 210 as a square shaped corner member 210 having four sides which are adjoined to each other to create four vertical sharp edges or corners, it is envisaged that, in other implementations, the corner member 210 may have any other shape (e.g. may be hexagonal shaped, or may be circular shaped, and/or may be free of any sharp edges or corners).

As shown in FIG. 2A and FIG. 2B, each (e.g. a single) primary mating element 211 of the corner member 210 may be disposed at a respective (e.g. single) side of the corner member 210. Accordingly, each side of the corner member 210 may include a respective (e.g. one) primary mating element 211. It is envisaged that, in other implementations, each side of the corner member 210 may include more than one primary mating element 211. For example, in other implementations, each side of the corner member 210 may include two or more primary mating elements 211. For example, the two or more primary mating elements 211, in other implementations, may be extending vertically and/or parallel with each other, on the same side of the corner member 210.

Referring to FIG. 2A, according to various aspects, the stiffener assembly 200 may include a number of frame members 220 equal to a number of primary mating elements 211 of the corner member 210. For example, as shown in FIG. 2A, the stiffener assembly 200 may include a first frame member 220a configured to interlock with a first primary mating element 211a of the corner member 210 at a first side of the corner member 210. The stiffener assembly 200 may include (e.g. optionally or further include) a second frame member 220b configured to interlock with a second primary mating element 211b of the corner member 210 at a second side of the corner member 210 (e.g. immediately adjacent to and adjoining the first side of the corner member 210). The stiffener assembly 200 may include (e.g. optionally or further include) a third frame member 220c configured to interlock with a third primary mating element 211c of the corner member 210 at a third side of the corner member 210 (e.g. immediately adjacent to and adjoining the second side of the corner member 210, and being opposite to the first side). The stiffener assembly 200 may include (e.g. optionally or further include) a fourth frame member 220d configured to interlock with a fourth primary mating element 211d of the corner member 210 at a fourth side of the corner member 210 (e.g. immediately adjacent to and adjoining the third side of the corner member 210). It is envisaged that, in other implementations, the stiffener assembly 200 may have any other number of frame members 220 and primary mating elements 211. For example, in other implementations, the stiffener assembly 200 may have (e.g. have only) (i) the first frame member 220a and the first primary mating element 211a of the corner member 210 at the first side of the corner member 210 and (ii) the second frame member 220b and the second primary mating element 211b of the corner member 210 at the second side of the corner member 210 (e.g. immediately adjacent to and adjoining the first side of the corner member 210). As another example, in other implementations, the stiffener assembly 200 may have (e.g. have only) (i) the first frame member 220a and the first primary mating element 211a of the corner member 210 at the first side of the corner member 210 and (ii) the third frame member 220c and the third primary mating element 211c of the corner member 210 at the third side of the corner member 210 (e.g. opposite to the first side).

FIG. 2C is an isolated perspective view of a frame member of the stiffener assembly of FIG. 2A, according to various aspects.

With reference to FIG. 2C, each frame member 220 may include a plurality of secondary mating elements 221 (e.g. a plurality of end portions). As an example, shown in FIG. 2C, the frame member 220 may include two secondary mating elements 221 (e.g. two opposite end portions), on opposite ends of the frame member 220, configured to mate (e.g. interlock) with corresponding primary mating elements 221 of the corner member 210.

According to various aspects, the entire frame member 220 may be a single and/or monolithic structure or entity. That is, the entire frame member 220 may be an integral structure or may be integrally formed (e.g. free from any disparate or separable parts or portions). Accordingly, the secondary mating elements 221 may be integral elements or portions of the frame member 220.

Referring back to FIG. 2A, according to various aspects, a shape (e.g. a lateral cross-sectional profile) of each secondary mating element 221 may correspond to a shape (e.g. a lateral cross-sectional profile) of a corresponding primary mating element 211 (i.e. configured to interlock with that secondary mating element 221). For example, as shown, both the primary mating element 211 and the secondary mating element 221 may have a polygonal (e.g. four-sided polygon, such as a rectangular) shape.

According to various aspects, a size of the secondary mating element 221 may be smaller than a size of the primary mating element 211. Accordingly, the secondary mating element 221 may be inserted into or fit into (i.e. may interlock) with the primary mating element 211, while the primary mating element 211 permits movement (e.g. limited movement) of the secondary mating element 221 within (i.e. relative to) the primary mating element 211.

With reference to FIG. 2A, to assemble the stiffener assembly 200, the secondary mating element 221 (e.g. end portion) of each frame member 220 may be inserted into a corresponding primary mating element 211 (e.g. opening) of the corner member 210, from at least the first entrance (i.e. at the upper surface of the corner member 210). Consequently, each interlocking pair of primary mating element 211 and secondary mating element 221 may form a corresponding or respective connection joint that permits movement (e.g. limited movement) of that secondary mating element 221 relative to (e.g. within) that primary mating element 211. According to various aspects, the relative movement of any secondary mating element 221 (i.e. interlocking with a corresponding primary mating element 211 of the corner member 210) may be independent of that of other remaining secondary mating elements 221 (i.e. which are interlocking with other remaining primary mating elements 211 of the corner member 210)

FIG. 2D is a plan view of the stiffener assembly of FIG. 2A, according to various aspects.

With reference to FIG. 2D, according to various aspects, a first width of each primary mating element 211 (e.g. measured longitudinally or along a longitudinal axis of the primary mating element 211) may be larger or wider than a first width of a corresponding secondary mating element 221 (e.g. measured longitudinally or along a longitudinal axis of the secondary mating element 221).

As a result, as shown in FIG. 2D, within a fully assembled stiffener assembly 200 (e.g. under normal conditions, which do not induce any warpage), with the primary mating element 211 interlocking with the secondary mating element 221, the stiffener assembly 200 may include a first spacing (or gap) 231 between the primary mating element 211 and the secondary mating element 221 which permits movement of the secondary mating element 221 relative to the primary mating element 211 in a first direction (herein referred to as “first longitudinal direction”) that is longitudinal (or lengthwise) of the frame member 220 and towards the corner member 210. The first spacing 231 may be between a first side surface (e.g. inner side surface) of the primary mating element 211 and an opposing first side surface of the secondary mating element 221.

Additionally, or alternatively, with reference to FIG. 2D, with the primary mating element 211 interlocking with the secondary mating element 221, the stiffener assembly 200 may include a second spacing (or gap) 232 between the primary mating element 211 and the secondary mating element 221 which permits movement of the secondary mating element 221 relative to the primary mating element 211 in a second direction (herein referred to as “second longitudinal direction”) that is longitudinal (or lengthwise) of the frame member 220 and away from the corner member 210. The second longitudinal direction may be opposite the first longitudinal direction. The second spacing 232 may be between a second side surface (e.g. inner side surface) of the primary mating element 211 and an opposing second side surface of the secondary mating element 221.

Hence, the connection joint formed between the interlocking primary mating element 211 and secondary mating element 221 may permit movement (e.g. limited movement) of the secondary mating element 221 of the frame member 220 in at least one direction or in two opposite directions that may be longitudinal (or lengthwise) of the frame member 220.

With reference to FIG. 2D, a side of the corner member 210 (i.e. where the second side surface of the primary mating element 211 is located) may include a through-hole 215 for (e.g. to allow) a body 223 of the frame member 220 (e.g. an elongate body 223, at an intermediate portion of the frame member 220) to pass or extend across. As such, a size (e.g. width, measured laterally) of the through-hole 215 may be substantially equal to or larger than a size (e.g. width, measured laterally) of the body 223 of the frame member 220. However, as shown, the size (e.g. width) of the through-hole 215 may be smaller than a size (e.g. a width, measured laterally) of the secondary mating element 221, to prevent the secondary mating element 221 from slipping out or disengaging from the primary mating element 211 in the second longitudinal direction. Moreover, the secondary mating element 221 may be configured and/or shaped as a “flange” (or may be a flanged portion, or a flanged-like portion, of the frame member 220) which extends sideways or laterally from an end of the body 223 of the frame member 220.

With reference to FIG. 2D, according to various aspects, a second width of each primary mating element 211 (e.g. measured laterally of the primary mating element 211) may be larger or wider than a second width of a corresponding secondary mating element 221 (e.g. measured laterally of the secondary mating element 221).

As a result, as shown in FIG. 2D, within a fully assembled stiffener assembly 200 (e.g. under normal conditions, which do not induce any warping), with the primary mating element 211 interlocking with the secondary mating element 221, the stiffener assembly 200 may include a third spacing (or gap) 233 between the primary mating element 211 and the secondary mating element 221 which permits movement of the secondary mating element 221 relative to the primary mating element 211 in a third direction (herein referred to as “first lateral direction”) that is lateral (or widthwise) of the frame member 220. The third spacing 233 may be between a third side surface (e.g. inner side surface) of the primary mating element 211 and an opposing third side surface of the secondary mating element 221.

Additionally, or alternatively, as shown in FIG. 2D, with the primary mating element 211 interlocking with the secondary mating element 221, the stiffener assembly 200 may include a fourth spacing (or gap) 234 between the primary mating element 211 and the secondary mating element 221 which permits movement of the secondary mating element 221 relative to the primary mating element 211 in a fourth direction (herein referred to as “second lateral direction”) that is lateral (or widthwise) of the frame member 220 and opposite the first lateral direction. The fourth spacing 234 may be between a fourth side surface (e.g. inner side surface) of the primary mating element 211 and an opposing fourth side surface of the secondary mating element 221.

Hence, the connection joint formed between the interlocking primary mating element 211 and secondary mating element 221 may permit movement (e.g. limited movement) of the secondary mating element 221 of the frame member 220 in at least one direction or in two opposite directions that may be lateral (or widthwise) of the frame member 220 and/or perpendicular to the aforementioned first and second longitudinal directions.

According to various aspects, the aforementioned spacings 231, 232, 233, and 234 may correspond to “threshold values”, or “clearances” within the stiffener assembly 200, for controlling an extent of potential warpage that a semiconductor assembly (e.g. which the stiffener assembly 200 is attached to) may undergo or experience. According to various aspects, these “threshold values” (or “clearances”) may be determined or engineered through simulations (e.g. based on the selection of materials of components within a semiconductor assembly, geometries of components, and/or assembly handling conditions which may include temperature fluctuations, etc.). The “threshold values” (or “clearances”) may be adjustable (e.g. based on warpage control requirements, particularly at high and low temperatures).

According to various aspects, under normal conditions (e.g. room temperature), which do not induce any warpage, the secondary mating element 221 may be entirely spaced apart from the primary mating element 211 (e.g. from all inner surface(s) of the corner member 210 that define the primary mating element 211) as shown in FIG. 2D. In other words, according to various aspects, the secondary mating element 221 may interlock with the primary mating element 211 in a manner such that the secondary mating element 221 loosely fits or loosely sits within the primary mating element 211. For instance, referring to the example in FIG. 2D, under normal conditions, which do not induce any warpage, a fully assembled stiffener assembly 200 may include all of the first to fourth spacings 231 to 234 described above. Accordingly, according to various aspects, a connection joint formed between the primary mating element 211 and the secondary mating element 221 may permit movement of the secondary mating element 221 relative to the primary mating element 211 in any direction (e.g. any horizontal direction) around the secondary mating element 221, until the secondary mating element 221 abuts or engages (e.g. contacts) the primary mating element 211 to prevent further movement. Accordingly, the stiffener assembly 200, when attached to a semiconductor assembly, may control an extent of potential warpage that the semiconductor assembly may undergo, in any direction (e.g. any horizontal direction) and/or range that the secondary mating element 221 may be permitted to move within the stiffener assembly 200.

FIG. 2E is a plan view of a stiffener assembly within a semiconductor assembly, according to various aspects.

According to various aspects, there may be provided an apparatus which may include or may be the stiffener assembly 200A.

The stiffener assembly 200A may include a plurality of the corner members 210 (described above) and a plurality of the frame members 220 (described above). As shown in FIG. 2E, the plurality of corner members 210 may be interlocking with the plurality of frame members 220, within the stiffener assembly 200A, such that the plurality of corner members 210 may be inter-connected to each other via the plurality of frame members 220.

As shown in FIG. 2E, the stiffener assembly 200A may be integrated within an assembly, which may include or may be a semiconductor assembly 2000 (e.g. a panel-level package or packaging), to enhance the mechanical integrity or rigidity of the semiconductor assembly 2000. The semiconductor assembly 2000 may include a semiconductor substrate or panel 2001 (i.e. a first component of the semiconductor assembly 2000) as well as a plurality of chips 2002 (i.e. a plurality of second components of the semiconductor assembly 2000) disposed on an upper surface of the semiconductor substrate 2001. Further, the semiconductor assembly 2000 may include an intervening element (not shown in FIG. 2E), such as the intervening element 1003 (e.g. mold material) described above with reference to FIG. 1A.

According to various aspects, each corner member 210 of the stiffener assembly 200A may be extending (e.g. vertically) across the semiconductor substrate 2001, for instance across a corresponding through-hole or via (e.g. via hole) of the semiconductor substrate 2001.

The frame members 220 of the stiffener assembly 200A may be of a same height as the corner members 210 (see FIG. 2A) and, likewise to the corner members 210, may be extending (e.g. vertically) across the semiconductor substrate 2001.

A height of each of the corner members 210 and the frame members 220 of the stiffener assembly 200A may be taller than a height of the semiconductor substrate 2001. Accordingly, an upper portion (herein referred to as “protruding portion”) of each of the corner members 210 and the frame members 220 of the stiffener assembly 200A may be protruding out or upwards from the upper surface of the semiconductor substrate 2001. The protruding portions of the corner members 210 and the frame members 220 of the stiffener assembly 200A may be alongside or adjacent (e.g. on a same plane as) the plurality of chips 2002 disposed on the upper surface of the semiconductor substrate 2001.

According to various aspects, the chips 2002 may be physically apart from the protruding portions of the corner members 210 and the frame members 220 of the stiffener assembly 200A. In other words, the chips 2002 may be disposed around the protruding portions of the corner members 210 and the frame members 220, but may not be in physical contact therewith. However, the chips 2002 may be indirectly connected to at least the frame members 220 (e.g. to their protruding portions) via the intervening element (e.g. mold material) (not shown in FIG. 2E). It is envisaged that, in other implementations, at least some of the chips 2002 (e.g. immediately adjacent to the protruding portions of the frame members 220) may be in physical contact with the frame members 220 of the stiffener assembly 200A.

It is also envisaged that, in other implementations, the frame members 220 of the stiffener assembly 200A may be shorter than the corner members 210, such that the frame members 220 may be disposed on an upper surface of the semiconductor substrate 2001 but not extending across the entire semiconductor substrate 2001 like the corner members 210. Thus, in other implementations, the (shorter) frame members 220 of the stiffener assembly 200A may be interlocking with (e.g. with only) the protruding portions of the corner members 210 of the stiffener assembly 200A.

FIG. 2F is an isolated perspective view of an interlocked corner member and four frame members of the stiffener assembly of FIG. 2E, during a first warpage condition of the semiconductor assembly of FIG. 2E, according to various aspects.

According to various aspects, the semiconductor assembly 2000 of FIG. 2E may warp in a first manner which may resemble a “frown”, when subject to a first warpage condition. Specifically, under the first warpage condition, the semiconductor assembly 2000 may undergo a “convex warp”.

According to various aspects, under the first warpage condition, the frame members 220 may be pulled away (e.g. under tension) from the corner member 210, as shown in FIG. 2F, until it abuts a portion of the corner member 210 defining the primary mating elements 211.

In the above manner, the corner member 210 may restrict or constrain the frame members 220 and, by extension, the semiconductor substrate or panel 2001 and/or the plurality of chips 2002 (i.e. which may be coupled to the frame members 220) from any further potential warpage or movement, during the first warpage condition.

FIG. 2G is an isolated perspective view of an interlocked corner member and four frame members of the stiffener assembly of FIG. 2E, during a second warpage condition of the semiconductor assembly of FIG. 2E, according to various aspects.

According to various aspects, the semiconductor assembly 2000 of FIG. 2E may warp in a second manner which may resemble a “smile”, when subject to a second warpage condition. Specifically, under the second warpage condition, the semiconductor assembly 2000 may undergo a “concave warp”.

According to various aspects, under the second warpage condition, the frame members 220 may be pushed inwards (e.g. under compression) or towards the corner member 210, as shown in FIG. 2G, until it abuts a portion of the corner member 210 defining the primary mating elements 211.

In the above manner, the corner member 210 may restrict or constrain the frame members 220 and, by extension, the semiconductor substrate or panel 2001 and/or the plurality of chips 2002 (i.e. which may be coupled to the frame members 220) from any further potential warpage or movement, during the second warpage condition.

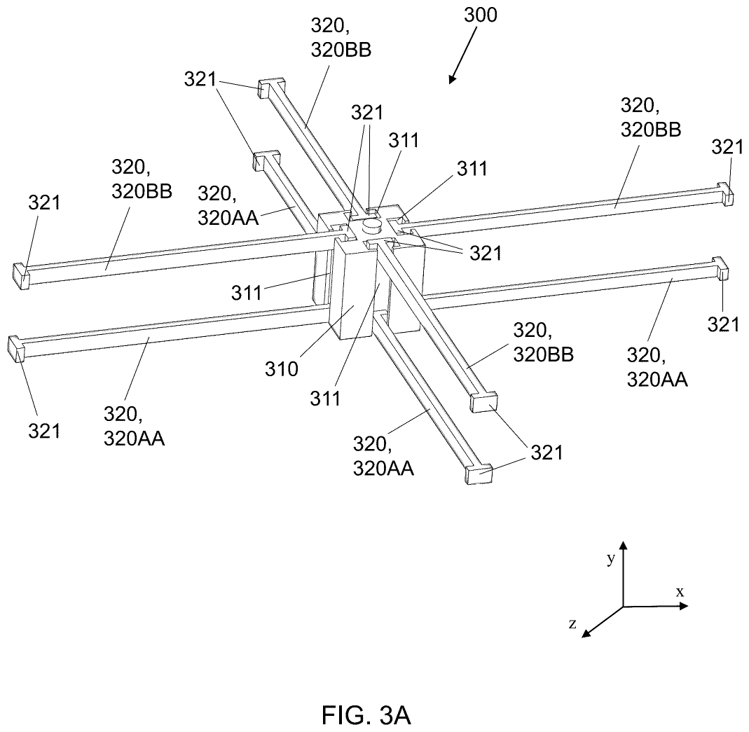

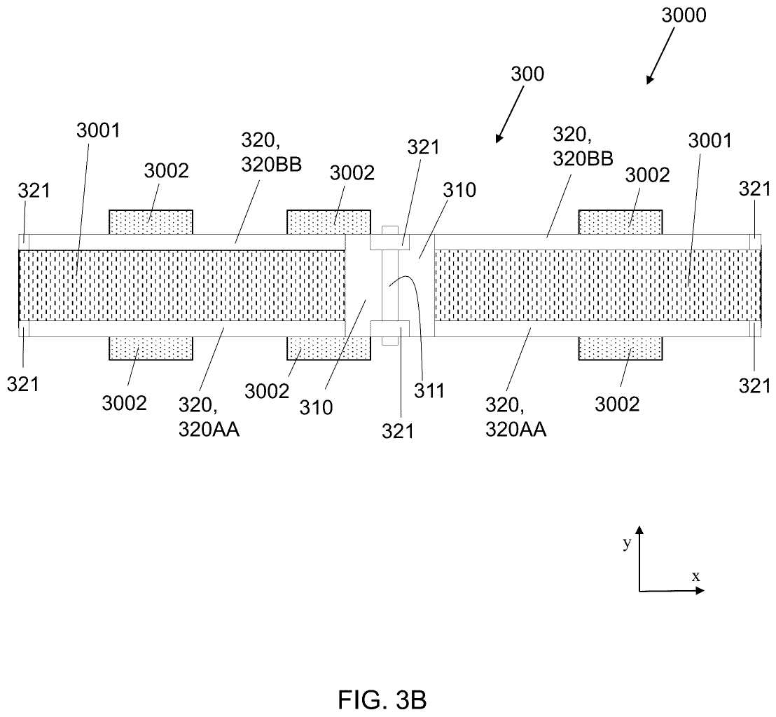

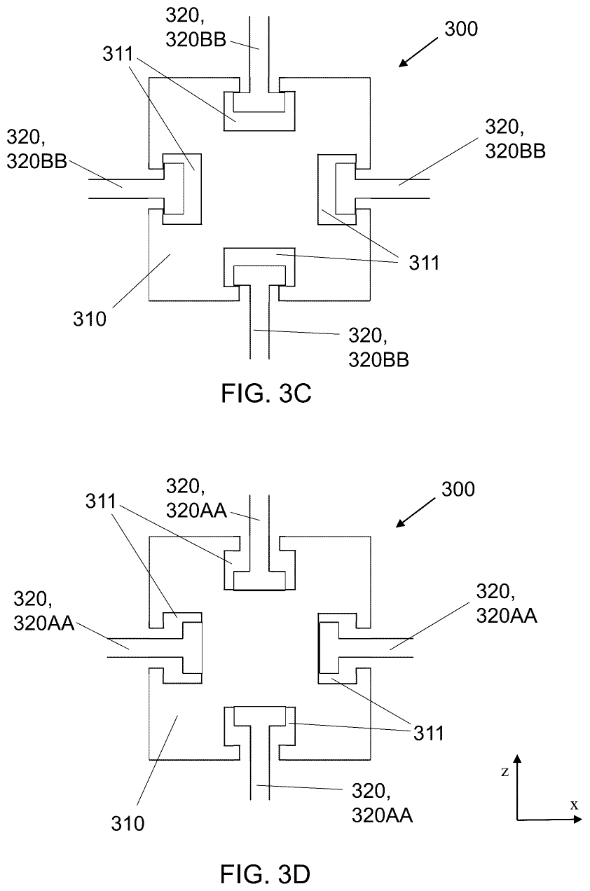

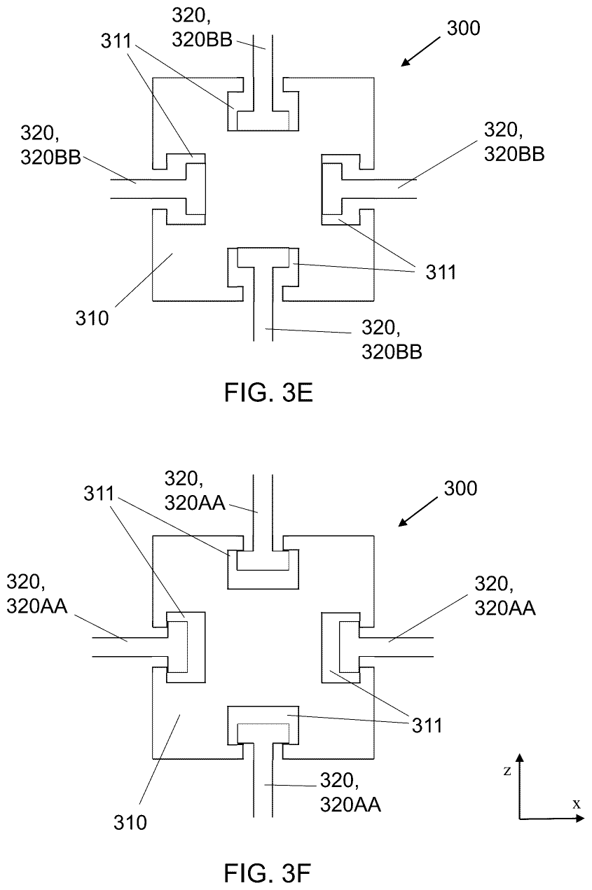

FIG. 3A is a perspective view of a stiffener assembly which includes a corner member interlocking with a plurality of frame members at each primary mating element of the corner member, according to various aspects.

According to various aspects, there may be provided an apparatus which may include or may be the stiffener assembly 300. According to various aspects, the stiffener assembly 300 may contain any one or more or all the features and/or limitations of the stiffener assembly 100 of FIG. 1A to FIG. 1F and/or the stiffener assembly 200 of FIG. 2A and/or the stiffener assembly 200A of FIG. 2E. In the following, the stiffener assembly 300 is described with like reference characters generally referring to the same or corresponding parts/features of the stiffener assembly 100 of FIG. 1A to FIG. 1F and/or the stiffener assembly 200 of FIG. 2A and/or the stiffener assembly 200A of FIG. 2E. The description of the parts/features made with respect to the stiffener assembly 300 may also be applicable with respect to the stiffener assembly 100 and/or 200 and/or 200A, and vice versa.

The stiffener assembly 300 of FIG. 3A may differ from the stiffener assembly 200 of FIG. 2A in that each primary mating element 311 of the corner member 310 of the stiffener assembly 300 of FIG. 3A may be capable of interlocking with a plurality of frame members 320. In other words, a plurality of frame members 320 of the stiffener assembly 300 may interlock with the same primary mating element 311 of the corner member 310 of the stiffener assembly 300.

Thus, a size (e.g. a height or length) of each primary mating element 311 of the corner member 310 may be larger (e.g. taller or longer) than a size (e.g. height or length) of each secondary mating element 321 of each frame member 320. As an example, shown in FIG. 3A, each primary mating element 311 of the corner member 310 (or the entire corner member 310 itself) may be at least (or more than) twice the height (or length) of each secondary mating element 321 of each frame member 320 (or the entire frame member 320 itself). Accordingly, as shown in FIG. 3A, each primary mating element 311 of the corner member 310 may interlock with at least two secondary mating elements 321 belonging to two discrete frame members 320 of the stiffener assembly 300. Hence, as shown, according to various aspects, a height of the primary mating element 311 may be taller than a combined height of two secondary mating elements 321. Specifically, at least two secondary mating elements 321 (e.g. end portions) may be insertable into (i.e. interlocked or interlocked with) each (e.g. a single) primary mating element 311 (e.g. configured as an elongate opening) of the corner member 310. Accordingly, when the corner member 310 includes four primary mating elements 311, as shown in FIG. 3A, the stiffener assembly 300 may include at least eight frame members 320 (with at least two frame members 320AA and 320BB interlocking with each primary mating element 311).

As shown in FIG. 3A, according to various aspects, at each primary mating element 311, a first frame member 320AA (which may also be referred to as a “bottom frame member” 320AA) may be at a first segment, such as a first end region (e.g. a bottom region), of the primary mating element 311, while a second frame member 320BB (which may also be referred to as an “upper frame member” 320BB) may be at a second segment, such as a second end region (e.g. an opposite and/or upper region), of the primary mating element 311.

It is envisaged that, in other implementations (not shown), at each primary mating element 311, the stiffener assembly 300 may include (e.g. optionally or further include) one or more further or additional frame member(s) at an intermediate portion of the primary mating element 311 (e.g. between the first segment and the second segment).

FIG. 3B is a side view of a semiconductor assembly having the stiffener assembly of FIG. 3B attached to an interposer, according to various aspects.

As shown in FIG. 3B, the stiffener assembly 300 may be integrated (e.g. as a “double-sided assembly”) within an assembly, which may include or may be a semiconductor assembly 3000, to enhance the mechanical integrity or rigidity of the semiconductor assembly 3000. The semiconductor assembly 3000 may include an interposer 3001 as well as a plurality of semiconductor components 3002 (e.g. chips or chiplets) on surfaces (e.g. bottom and upper surfaces) of the interposer 3001.

As shown, according to various aspects, the stiffener assembly 300 may be attached to the interposer 3001, with the interposer 3001 between (e.g. sandwiched between) the bottom frame members 320AA and the upper frame members 320BB of the stiffener assembly 300. That is, the bottom frame members 320AA may be at or on (e.g. directly on) the bottom surface of the interposer 3001, while the upper frame members 320BB of the stiffener assembly 300 may be at or on (e.g. directly on) the upper surface of the interposer 3001.

According to various aspects, as shown in FIG. 3B, the corner member 310 may be extending (e.g. vertically) across the interposer 3001, for instance across a corresponding through-hole or via (e.g. via hole that extends between the bottom and upper surfaces) of the interposer 3001.

According to various aspects, the interposer 3001 may be configured in a manner which enables the interposer 3001 to have electrical connectivity between its upper and bottom surfaces. For example, according to various aspects, the interposer 3001 may be embedded with electrical interconnects.

Additionally, according to various aspects, the corner member 310 and/or any one or more of the frame members 320, 320AA, or 320BB may include or may be composed of an electrically conductive material so that they may serve as electrical routes (e.g. distinct or inter-connected electrical routes) or “power distribution (or delivery) channels” across and/or along the interposer 3001. For instance, each discrete frame member 320, 320AA, or 320BB may serve as a distinct electrical route (e.g. a lateral or horizontal electrical route) that electrically connects at least two semiconductor components 3002 (e.g. chips or chiplets on a same horizontal surface of the interposer 3001). The corner member 310 that extends vertically across the interposer 3001 may serve as a vertical electrical route that electrically connects at least a pair of semiconductor components 3002 on opposite, bottom and upper surfaces of the interposer 3001.

Additionally, according to various aspects, the corner member 310 and/or any one or more of the frame members 320, 320AA, or 320BB may include or may be composed of a thermally conductive material so that they may serve as thermal conductive routes or “thermal dissipation paths” (e.g. in horizontal and/or vertical directions) for conducting heat.

As some examples, the corner member 310 and the frame members 320 may be composed of a metal (e.g. Copper, Steel, Aluminium) or an alloy (e.g. Aluminium-Silicon alloy, such as “Aluminium Silicon Copper” or “AlSiCu”). According to various aspects, the corner member 310 may be composed of a same material as the frame members 320. It is envisaged that, in other aspects, the corner member 310 may be composed of a different material from the frame members 320.

FIG. 3C is an isolated plan view of the corner member and upper frame members of the stiffener assembly at an upper region of the corner member, when the semiconductor assembly of FIG. 3B is warped in a first manner, according to various aspects.

FIG. 3D is an isolated plan view of the corner member and bottom frame members at a bottom region of the corner member, when the semiconductor assembly of FIG. 3B is warped in the first manner, according to various aspects.

According to various aspects, the semiconductor assembly 3000 of FIG. 3B may warp in a first manner which may resemble a “frown”, when subject to a first warpage condition. Specifically, under the first warpage condition, the semiconductor assembly 3000 may undergo a “convex warp”.

It is envisaged that, in other aspects, the semiconductor assembly 3000 may undergo a “saddle” shaped deformation (e.g. having a “convex warp” in the x-axis and a “concave warp” in the z-axis, or having a “concave warp” in the x-axis and a “convex warp” in the z-axis).

According to various aspects, under the first warpage condition, the upper frame members 320BB may be pulled away (e.g. under tension) from the corner member 310 until they abut a portion of the corner member 310 defining the primary mating elements 311 (as shown in FIG. 3C), while the bottom frame members 320AA may be pushed inwards (e.g. under compression) or towards the corner member 310 until they abut another portion of the corner member 310 defining the primary mating elements 311 (as shown in FIG. 3D).

In the above manner, the corner member 310 may restrict or constrain the upper frame members 320BB and the bottom frame members 320AA and, by extension, the interposer 3001 and/or the semiconductor components 3002 (i.e. which may be coupled to the frame members 320AA and 320BB) from any further potential warpage or movement, during the first warpage condition.

FIG. 3E is an isolated plan view of the corner member and upper frame members of the stiffener assembly at an upper region of the corner member, when the semiconductor assembly of FIG. 3B is warped in a second manner, according to various aspects.

FIG. 3F is an isolated plan view of the corner member and bottom frame members at a bottom region of the corner member, when the semiconductor assembly of FIG. 3B is warped in the second manner, according to various aspects.

According to various aspects, the semiconductor assembly 3000 may warp in a second manner which may resemble a “smile”, when subject to a second warpage condition. Specifically, under the second warpage condition, the semiconductor assembly 3000 may undergo a “concave warp”.

According to various aspects, under the second warpage condition, the upper frame members 320BB may be pushed inwards (e.g. under compression) or towards the corner member 310 until they abut a portion of the corner member 310 defining the primary mating elements 311 (as shown in FIG. 3E), while the bottom frame members 320AA may be pulled away (e.g. under tension) from the corner member 310 until they abut another portion of the corner member 310 defining the primary mating elements 311 (as shown in FIG. 3F).

In the above manner, the corner member 310 may restrict or constrain the upper frame members 320BB and the bottom frame members 320AA and, by extension, the interposer 3001 and/or the semiconductor components 3002 (i.e. which may be coupled to the frame members 320AA and 320BB) from any further potential warpage or movement, during the second warpage condition.

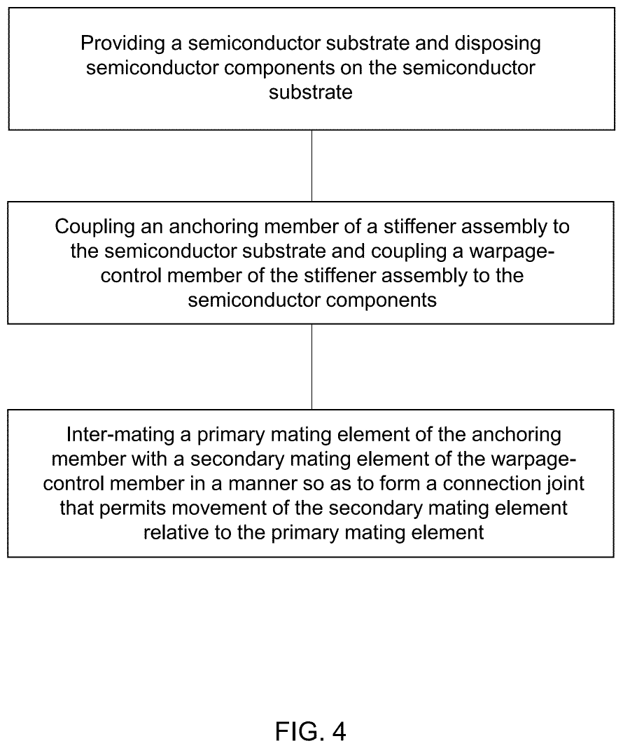

FIG. 4 is a flow chart depicting a method, according to various aspects.

According to various aspects, the method (e.g. a method of making or assembling an assembly, such as a semiconductor assembly) may include providing the first component 1001, 2001, or 3001 (e.g. a semiconductor substrate).

The method may include (e.g. further include) disposing the second component(s) 1002, 2002, or 3002 (e.g. one or more semiconductor components) on the first component 1001, 2001, or 3001 (e.g. semiconductor substrate).

The method may include (e.g. further include) coupling the corner member 110, 210, or 310 to the first component 1001, 2001, or 3001 (e.g. semiconductor substrate).

The method may include (e.g. further include) coupling the frame member 120, 220, or 320 to the second component(s) 1002, 2002, or 3002 (e.g. one or more semiconductor components).

The method may include (e.g. further include) interlocking the primary mating element 111, 211, or 311 of the corner member 110, 210, or 310 with the secondary mating element 121, 221, or 321 of the frame member 120, 220, or 320 in a manner so as to form the connection joint (therebetween) that permits movement of the secondary mating element 121, 221, or 321 relative to the primary mating element 111, 211, or 311.

The method may include (e.g. further include) providing a second corner member 110a, 210, or 310 and coupling the second corner member 110a, 210, or 310 to the first component 1001, 2001, or 3001 (e.g. semiconductor substrate). Further, the method may include interlocking the primary mating element 111a, 211, or 311 of the second corner member 110a, 210, or 310 with the further secondary mating element 121a, 221, or 321 of the frame member 120, 220, or 320 in a manner so as to form a further connection joint (therebetween) that permits movement of the further secondary mating element 121a, 221, or 321 relative to the primary mating element 111a, 211, or 311 of the second corner member 110a, 210, or 310.

The method may include (e.g. further include) providing or disposing the intervening element 1003 (e.g. mold material) between the frame member 120, 220, or 320 and the second component(s) 1002, 2002, or 3002 (e.g. one or more semiconductor components). The intervening element 1003 may be continuous between the frame member 120, 220, or 320 and the second component(s) 1002, 2002, or 3002, and may encapsulate or encase at least a portion of the frame member 120, 220, or 320 and at least a portion of the second component(s) 1002, 2002, or 3002.

The method may include (e.g. further include) curing the intervening element 1003 (e.g. mold material) until it solidifies.

While the disclosure has been particularly shown and described with reference to specific aspects, it should be understood by those skilled in the art that various changes, modification, and variation in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

To more readily understand and put into practical effect the present cleaning assembly, cleaning system, and method, they will now be described by way of examples. For the sake of brevity, duplicate descriptions of features and properties may be omitted.

### EXAMPLES

Example 1 provides a stiffener assembly. The stiffener assembly may include an anchoring member configured to be coupled to a first component of a semiconductor assembly. The anchoring member may include a primary mating element. The stiffener assembly may further include a warpage-control member configured to be coupled to a second component of the semiconductor assembly. The warpage-control member may include a secondary mating element. The primary mating element of the anchoring member and the secondary mating element of the warpage-control member may be configured to inter-mate with each other to form a connection joint that permits movement of the secondary mating element relative to the primary mating element.

Example 2 provides an apparatus (e.g. a stiffener assembly). The apparatus may include a corner member configured to be coupled to a first component of a semiconductor assembly. The corner member may include an (e.g. at least one) opening. The apparatus may further include a frame member configured to be coupled to a second component of the semiconductor assembly. The frame member may include an end portion. The opening of the corner member and the end portion of the frame member may be configured to interlock with each other (or may be interlocked with each other) to form a connection joint that permits movement of the end portion of the frame member relative to (e.g. within) the opening of the corner member.

Example 3 may include the apparatus of example 2 and/or any other example disclosed herein, for which, with the corner member coupled to the first component of the semiconductor assembly, the corner member extends in a first direction relative to the first component and, for which, with the frame member coupled to the second component of the semiconductor assembly, the frame member extends in a second direction that is non-parallel to the first direction and, for which, the connection joint may be configured to permit movement of the end portion of the frame member in at least the second direction.

Example 4 may include the apparatus of example 3 and/or any other example disclosed herein, for which, with the corner member coupled to the first component of the semiconductor assembly, the corner member extends in a first direction relative to the first component and, for which, with the frame member coupled to the second component of the semiconductor assembly, the frame member extends in a second direction that is non-parallel to the first direction and, for which, the connection joint may be configured to permit movement of the end portion of the frame member in at least a third direction that is non-parallel to both the first direction and the second direction.

Example 5 may include the apparatus of example 2 and/or any other example disclosed herein, for which, with the connection joint formed, an inner surface of the corner member that defines the opening of the corner member at least partially surrounds a side surface of the end portion of the corner member.

Example 6 may include the apparatus of example 2 and/or any other example disclosed herein, for which, the opening of the corner member extends from an upper surface of the corner member towards a base surface of the corner member and, for which, the end portion of the frame member is insertable into the opening of the corner member from the upper surface of the corner member.

Example 7 may include the apparatus of example 2 and/or any other example disclosed herein, for which, a shape of the opening of the corner member corresponds to a shape of the end portion of the frame member and, for which, a size of the opening of the corner member is larger than a size of the end portion of the frame member.

Example 8 may include the apparatus of example 7 and/or any other example disclosed herein, for which, the opening of the corner member is a polygonal shaped opening and, for which, the end portion of the frame member is a corresponding polygonal shaped end portion.

Example 9 may include the apparatus of example 2 and/or any other example disclosed herein, for which, the frame member includes an elongate body and, for which, the end portion of the frame member is at a first end of the elongate body and, for which the frame member includes a further end portion at a second opposite end of the elongate body.

Example 10 may include the apparatus of example 9 and/or any other example disclosed herein, for which, the apparatus may further include a second corner member, the second corner member having an opening and, for which, the opening of the second corner member and the further end portion of the frame member may be configured to interlock with each other to form a further connection joint that permits movement of the further end portion of the frame member relative to the opening of the second corner member.

Example 11 may include the apparatus of example 2 and/or any other example disclosed herein, for which, the corner member further includes a further opening and, for which, the apparatus may further include a second frame member, the second frame member having an end portion. The further opening of the corner member and the end portion of the second frame member may be configured to interlock with each other to form a further connection joint that permits movement of the end portion of the second frame member relative to the further opening of the corner member.

Example 12 may include the apparatus of example 2 and/or any other example disclosed herein, for which, the apparatus may further include a second frame member having an end portion and, for which, a height of the opening of the corner member may be taller than a combined height of both the end portion of the frame member and the end portion of the second frame member and, for which, both the end portion of the frame member and the end portion of the second frame member may be configured to interlock with the opening of the corner member, with the end portion of the frame member at a first region of the opening and with the end portion of the second frame member at a second region of the opening.

Example 13 may include the apparatus of example 2 and/or any other example disclosed herein, for which, the corner member may be composed of an electrically conductive material and, for which, the frame member may be composed of an electrically conductive material.

Example 14 may include the apparatus of example 2 and/or any other example disclosed herein, for which, the corner member may be composed of a thermally conductive material and, for which, the frame member may be composed of a thermally conductive material.

Example 15 provides an assembly (e.g. a semiconductor assembly). The assembly may include a semiconductor substrate as well as one or more semiconductor components on the semiconductor substrate. Further, the assembly may include an apparatus. The apparatus may include a corner member coupled to the semiconductor substrate, the corner member having an opening, and a frame member coupled to the one or more semiconductor components, the frame member having an end portion. The opening of the corner member and the end portion of the frame member may be interlocked with each other to form a connection joint that permits movement of the end portion relative to (e.g. within) the opening.

Example 16 may include the assembly of example 15 and/or any other example disclosed herein, for which, the frame member may be on an upper surface of the semiconductor substrate.

Example 17 may include the assembly of example 15 and/or any other example disclosed herein, for which, the corner member may be on an upper surface of the semiconductor substrate.

Example 18 may include the assembly of example 15 and/or any other example disclosed herein, for which, the corner member may be at least partially within the semiconductor substrate and may be extending in a thickness direction of the semiconductor substrate.

Example 19 may include the assembly of example 15 and/or any other example disclosed herein, for which, the assembly may further include a mold material between the frame member and the one or more semiconductor components.

Example 20 provides a method. The method may include providing a semiconductor substrate. The method may further include disposing one or more semiconductor components on the semiconductor substrate. The method may further include coupling a corner member of an apparatus to the semiconductor substrate. The method may further include coupling a frame member of the apparatus to the one or more semiconductor components. The method may further include interlocking an opening of the corner member with an end portion of the frame member in a manner so as to form a connection joint that permits movement of the end portion relative to the opening.

Example 21 may include the method of example 20 and/or any other example disclosed herein, for which, the method may further include disposing a mold material between the frame member and the one or more semiconductor components.

1. An apparatus comprising:
a corner member configured to be coupled to a first component of a semiconductor assembly, the corner member comprising an opening; and
a frame member configured to be coupled to a second component of the semiconductor assembly, the frame member comprising an end portion;
wherein the opening of the corner member and the end portion of the frame member are configured to interlock with each other to form a connection joint that permits movement of the end portion of the frame member relative to the opening of the corner member.

2. The apparatus of claim 1,
wherein, with the corner member coupled to the first component of the semiconductor assembly, the corner member extends in a first direction relative to the first component;
wherein, with the frame member coupled to the second component of the semiconductor assembly, the frame member extends in a second direction that is non-parallel to the first direction; and
wherein the connection joint is configured to permit movement of the end portion of the frame member in the second direction.

3. The apparatus of claim 1,
wherein, with the corner member coupled to the first component of the semiconductor assembly, the corner member extends in a first direction relative to the first component;
wherein, with the frame member coupled to the second component of the semiconductor assembly, the frame member extends in a second direction that is non-parallel to the first direction; and
wherein the connection joint is configured to permit movement of the end portion of the frame member in a third direction that is non-parallel to both the first direction and the second direction.

4. The apparatus of claim 1,
wherein, with the connection joint formed, an inner surface of the corner member that defines the opening of the corner member at least partially surrounds a side surface of the end portion of the corner member.

5. The apparatus of claim 1,
wherein the opening of the corner member extends from an upper surface of the corner member towards a base surface of the corner member;
wherein the end portion of the frame member is insertable into the opening of the corner member from the upper surface of the corner member.

6. The apparatus of claim 1,
wherein a shape of the opening of the corner member corresponds to a shape of the end portion of the frame member; and
wherein a size of the opening of the corner member is larger than a size of the end portion of the frame member.

7. The apparatus of claim 6,
wherein the opening of the corner member is a polygonal shaped opening; and
wherein the end portion of the frame member is a corresponding polygonal shaped end portion.

8. The apparatus of claim 1,
wherein the frame member comprises an elongate body;
wherein the end portion of the frame member is at a first end of the elongate body; and
wherein the frame member comprises a further end portion at a second opposite end of the elongate body.

9. The apparatus of claim 8, further comprising:
a second corner member, the second corner member comprising an opening; and
wherein the opening of the second corner member and the further end portion of the frame member are configured to interlock with each other to form a further connection joint that permits movement of the further end portion of the frame member relative to the opening of the second corner member.

10. The apparatus of claim 1,
wherein the corner member further comprises a further opening; and
wherein the apparatus further comprises:
a second frame member, the second frame member comprising an end portion;
wherein the further opening of the corner member and the end portion of the second frame member are configured to interlock with each other to form a further connection joint that permits movement of the end portion of the second frame member relative to the further opening of the corner member.

11. The apparatus of claim 1, further comprising:
a second frame member, the second frame member comprising an end portion;
wherein a height of the opening of the corner member is taller than a combined height of both the end portion of the frame member and the end portion of the second frame member; and
wherein both the end portion of the frame member and the end portion of the second frame member are configured to interlock with the opening of the corner member, with the end portion of the frame member at a first region of the opening and with the end portion of the second frame member at a second region of the opening.

12. The apparatus of claim 1,
wherein the corner member is composed of an electrically conductive material; and
wherein the frame member is composed of an electrically conductive material.

13. The apparatus of claim 1,
wherein the corner member is composed of a thermally conductive material; and
wherein the frame member is composed of a thermally conductive material.

14. An assembly comprising:
a semiconductor substrate;
one or more semiconductor components on the semiconductor substrate;
an apparatus comprising:
a corner member coupled to the semiconductor substrate, the corner member comprising an opening, and
a frame member coupled to the one or more semiconductor components, the frame member comprising an end portion,
wherein the opening of the corner member and the end portion of the frame member are interlocked with each other to form a connection joint that permits movement of the end portion relative to the opening.

15. The assembly of claim 14,
wherein the frame member is on an upper surface of the semiconductor substrate.

16. The assembly of claim 14,
wherein the corner member is on an upper surface of the semiconductor substrate.

17. The assembly of claim 14,
wherein the corner member is at least partially within the semiconductor substrate and is extending in a thickness direction of the semiconductor substrate.

18. The assembly of claim 14, further comprising:
a mold material between the frame member and the one or more semiconductor components.

19. A method comprising:
providing a semiconductor substrate;
disposing one or more semiconductor components on the semiconductor substrate;
coupling a corner member of an apparatus to the semiconductor substrate;
coupling a frame member of the apparatus to the one or more semiconductor components; and
interlocking an opening of the corner member with an end portion of the frame member in a manner so as to form a connection joint that permits movement of the end portion relative to the opening.

20. The method of claim 19, further comprising:
disposing a mold material between the frame member and the one or more semiconductor components.
